(19) United States
(12) Patent Application Publication
(10) Pub. No.: US 2026/0215295 A1
(43) Pub. Date: Jul. 23, 2026

(54) ELECTRONIC STACKED STRUCTURE AND MANUFACTURING METHOD THEREOF

(71) Applicant: NANYA TECHNOLOGY CORPORATION, New Taipei City (TW)

(72) Inventor: Hsu Chiang, New Taipei City (TW)

(73) Assignee: NANYA TECHNOLOGY CORPORATION, New Taipei City (TW)

(21) Appl. No.: 19/026,669

(22) Filed: Jan. 17, 2025

(51) Int. Cl. H01L 23/538; H01L 23/498

(52) U.S. Cl. CPC H10W 70/611; H10W 70/635; H10W 90/701

(57) ABSTRACT

The disclosure provides an electronic stacked structure including a first device, an insulating block, and a second device. The first device includes a first circuit layer and through vias disposed on the first circuit layer. The through vias comprise a functional through via and a dummy through via. The insulating block is directly covering and contacting the dummy through via. The second device includes a second circuit layer. The first circuit layer is electrically connected to the second circuit layer through the functional through via. An electronic stacked structure is also provided.

### BACKGROUND

### Technical Field

The present disclosure relates to an electronic stacked structure and manufacturing method thereof.

### Description of Related Art

Three-dimensional stacking technology has been widely adopted to produce compact packages. Moreover, through vias are used to provide vertical signal and power transmission. In the design of the three-dimensional stacking structure, how to control transmission states of the through vias may be an important issue.

### SUMMARY

The disclosure provides an electronic stacked structure including a first device, an insulating block, and a second device. The first device includes a first circuit layer and through vias disposed on the first circuit layer. The through vias comprise a functional through via and a dummy through via. The insulating block is directly covering and contacting the dummy through via. The second device includes a second circuit layer. The first circuit layer is electrically connected to the second circuit layer through the functional through via.

The disclosure provides a manufacturing method of an electronic stacked structure including providing a first device, wherein the first device comprises a first circuit layer and through vias disposed on the first circuit layer, and the through vias comprise a functional through via and a dummy through via; forming an insulating block on the dummy through via; providing a second device, wherein the second device comprises a second circuit layer; and bonding the second device to the first device, wherein the first circuit layer is electrically connected to the second circuit layer by the functional through via.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 7 are cross-sectional views illustrating a manufacturing method of an electronic stacked structure according to an embodiment of the disclosure.

FIG. 8 is a flow diagram of some embodiments of a manufacturing method of an electronic stacked structure.

### DESCRIPTION OF THE EMBODIMENTS

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

In a 3D electronic structure, multiple devices are vertically stacked in a 3D space to achieve optimal effect of increasing capacity. Further, the vertical signal and the power are transmitted between different devices through the through vias, and a problem may be derived. To be specific, circuit layouts of the different devices may be changed according to actual design requirements. For example, a number of functional vias required in each device varies, therefore, circuit layouts need to redesign in the different devices. For example, fuse circuits may be used in the 3D electronic structure to turn off portions of the through vias to render it disconnected. However, redesign the circuit layouts is complicated in manufacturing, the fuse circuits may consume a size of the 3D electronic structure. In the present disclosure, for using the insulating block, the transmission states of the through vias may be controlled, the size of the 3D electronic structure may be improved, and the manufacturing cost may be decreased.

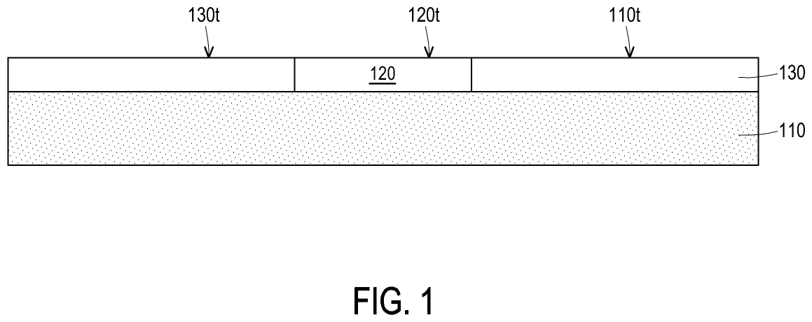

FIG. 1 to FIG. 7 are cross-sectional views illustrating a manufacturing method of an electronic stacked structure according to an embodiment of the disclosure. The electronic stacked structure may be implemented as a stacked memory device in the following embodiment, but the disclosure is not limited thereto. In other embodiment, the electronic stacked structure may be other suitable 3D electronic structure, such as a stacked logic device or the like.

Referring to FIG. 1, a memory cell 120 is formed on a semiconductor layer 110. In unillustrated portion, the semiconductor layer 110 is a silicon layer having at least one suitable doping region, and the memory cell 120 is defined as 1T1C, which refers to a structure including a combination of one transistor and one capacitor. For example, the transistor includes a gate structure, a source region, and a drain region to maintain the operation of the memory cell 120, wherein the gate structure may be formed on the semiconductor layer 110, and the source region/the drain region may be formed in the semiconductor layer 110. Here, the semiconductor layer 110 and the memory cell 120 may be manufactured by suitable general knowledge, the detail is no reiterated here.

And then, an isolation layer 130 may be formed on the semiconductor layer 110 and surrounding the memory cell 120. In some embodiments, the materials of the isolation layer 130 may be formed and covered a surface 110t of the semiconductor layer 110 and a surface 120t of the memory cell 120 (not shown). Next, a planarization process is performed to remove the materials overlying the surface 120t of the memory cell 120, such that the surface 120t of the memory cell 120 and a surface 130t of the isolation layer 130 are substantially coplanar, meanwhile the surface 120t of the memory cell 120 may be exposed. By doing so, flatness for forming subsequent films is increased, and the reliability of the electronic stacked structure may be improved. Here, the surface 110t of the semiconductor layer 110, the surface 120t of the memory cell 120, and the surface 130t of the isolation layer 130 may be top surfaces in FIG. 1.

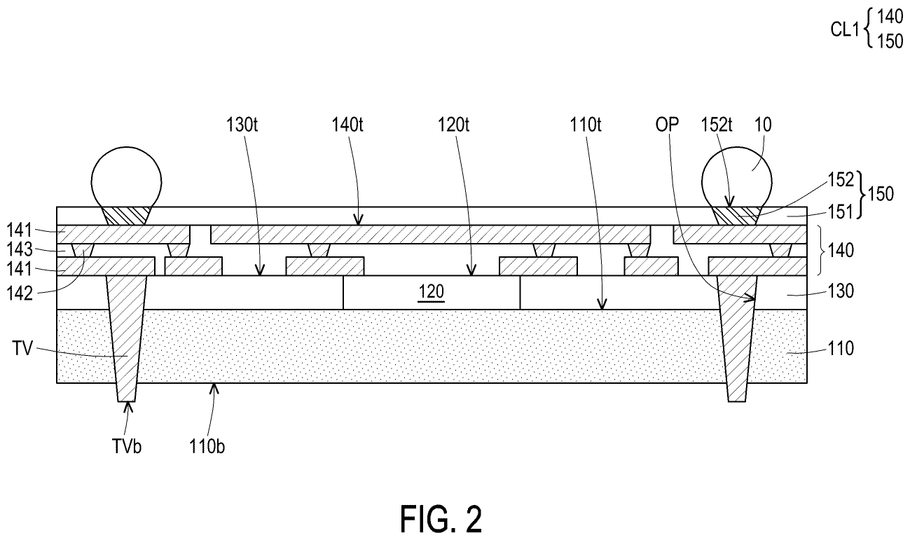

Referring to FIG. 2, a plurality of openings OP may be formed and penetrating through the semiconductor layer 110 and the isolation layer 130. Next, a plurality of through vias TV are formed in the openings OP. In the embodiment, the through vias TV are filled up the openings OP. In some embodiments, the openings OP are formed by photolithography process or the like, and the through vias TV are formed by plating process with the Cu, or the like. In some embodiments, when the semiconductor layer 110 is the silicon layer, an insulating layer may be formed between the through vias TV and the semiconductor layer 110 (not shown), and the through vias TV may be referred as TSVs.

After forming the through vias TV, a circuit layer CL1 is formed on the semiconductor layer 110 and electrically connected to the memory cell 120 and the through vias TV. For example, the circuit layer CL1 includes an interconnect structure 140 and a bonding structure 150, wherein the interconnect structure 140 is directly formed on the surface 120t of the memory cell 120 and the surface 130t of the isolation layer 130, and then the bonding structure 150 is directly formed on a surface 140t of the interconnect structure 140, that is to say, the bonding structure 150 is formed after forming the interconnect structure 140. Here, the surface 140t of the interconnect structure 140 may be a top surface in FIG. 2.

In the embodiment, the interconnect structure 140 includes a plurality of connecting lines 141 and a plurality of connecting vias 142 disposed in a plurality of dielectric layers 143, wherein the connecting lines 141 are electrically connected to the connecting vias 142. In some embodiments, the interconnect structure 140 may use depositing process with conductive materials and dielectric materials, photolithography process, etching process, chemical-mechanical polishing (CMP) process, or other suitable interconnect processes to form. For example, but not limited thereto, the conductive materials may include copper (Cu) or the like, and the dielectric materials include silicon oxide (SiO), phosphosilicate glass (PSG), borophosphosilicate glass (BPSG) or low dielectric constant (k) material, such as fluorosilicate glass (FSG), organosilicate glass (OSG), or a combination thereof.

Further, the bonding structure 150 includes a dielectric layer 151 and a plurality of bonding pads 152 disposed in the dielectric layer 151, wherein top surfaces 152t of the bonding pads are exposed for external connection. In some embodiments, the bonding structure 150 may use depositing process with conductive materials and dielectric materials, photolithography process, etching process, chemical-mechanical polishing (CMP) process, or other suitable interconnect processes to form.

After forming the circuit layer CL1, portions of the semiconductor layer 110 is removed from a side away from the circuit layer CL1 (such as a surface 110b opposite to the surface 110t) to reveal the through vias TV. In some embodiment, the removing process may be suitable thinning process, such as an etching process, the disclosure is not limited thereto. On the other hand, a plurality of external terminals 10 are formed on the bonding pads 152 and electrically connected thereto. In some embodiments, the external terminals 10 may be formed by reflowing process with solder or the like.

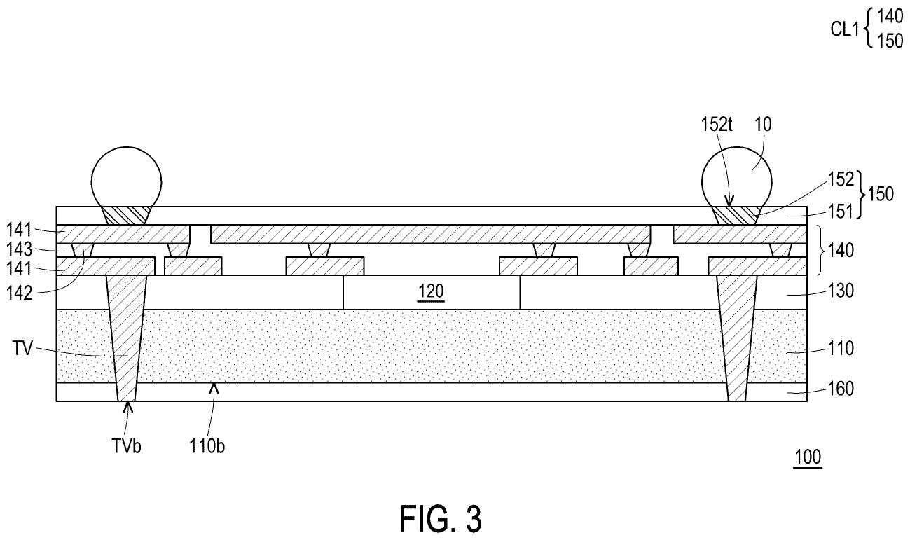

Referring to FIG. 3, a protection layer 160 is formed on the surface 110b of the semiconductor layer 110. For example, the protection layer 160 is filled in a space generated by removing the portions of the semiconductor layer 110. In some embodiments, the protection layer 160 may be formed as follow. First, the materials of the protection layer 160 is formed and covered a surface 110b of the semiconductor layer 110 and the surfaces TVb of the through vias TV (not shown). Next, a planarization process or an etching back process may be performed to remove the materials underlying the surfaces TVb of the through vias TV, such that the surface 110b of the semiconductor layer 110 and the surfaces TVb of the through vias TV may be substantially coplanar, and portions of the through vias TV are exposed. Here, the manufacturing of a device 100 is roughly completed via the above steps.

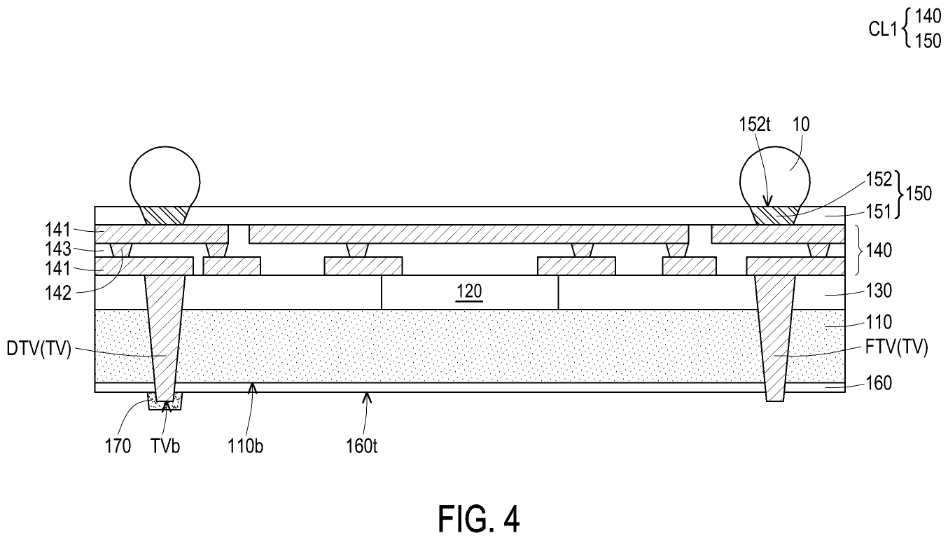

Referring to FIG. 4, the protection layer 160 is further removed and portions of the through vias TV protrude from a surface 160b of the protection layer 160, that is to say, sidewalls around bottom of the through vias TV are exposed. By doing so, bonding areas are increased, thereby the adhesion between the through vias TV and other components may be improved, but the disclosure is not limited thereto. The protection layer 160 may not be further removed following by FIG. 3.

In the embodiment, to illustrate, the through vias TV include a functional through via FTV and a dummy through via DTV. It should be noted that a number of the functional through via FTV and a number of the dummy through via DTV may depend on the actual design requirements, as long as at least one dummy through via DTV and at least one functional through via FTV are existed, it falls within the protection scope of the present disclosure.

In FIG. 4, an insulating block 170 is formed on the dummy through via DTV, to directly cover and contact the dummy through via DTV, such that the transmission from the dummy through via DTV may be disable due to the insulating block 170 blocking a conductive path below the dummy through via DTV. In some embodiment, a material of the protection layer 160 is different from a material of the insulating block 170. The protection layer 160 is deposited with oxide and the insulating block 170 is deposited with nitride. Based on selectivity between oxide and nitride, the insulating block 170 may be better to remove. For example, an insulating material is formed on the protection layer 160 fully at first. And then, a photolithography process and an etching process are performed to remove portions of the insulating material to form the insulating block 170 on desired position, such as near the dummy through via DTV.

In some embodiments, a thickness of the insulating block 170 ranges from 0.3 micrometers to 0.5 micrometers, and portions of the dummy through via DTV is embedded in the insulating block 170, but the disclosure is not limited thereto, as long as the dummy through via DTV is direct in contact with the insulating block 170, the blocking function of the insulating block 170 may be worked.

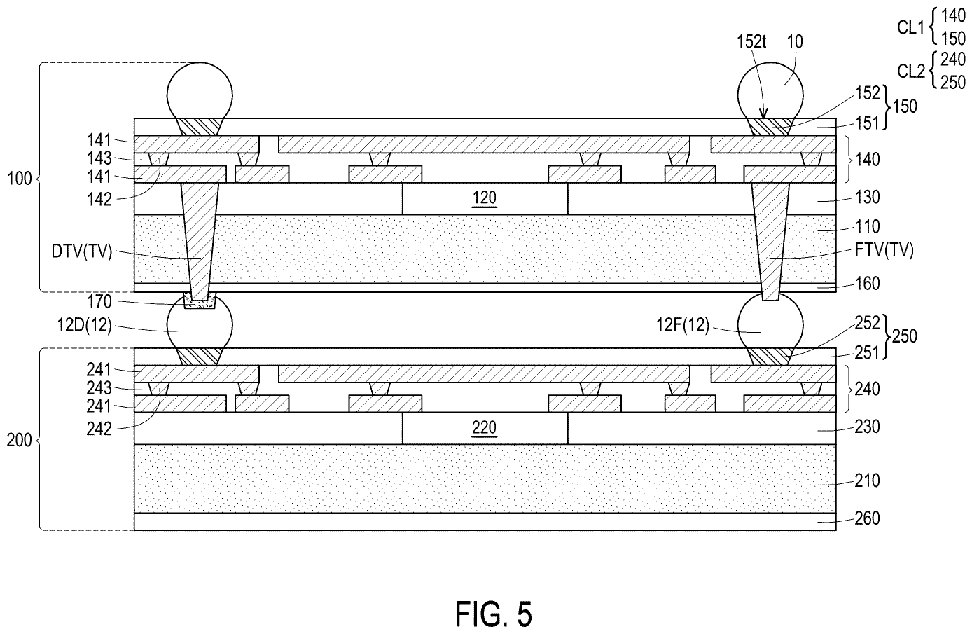

Referring to FIG. 5, a device 200 may be provided by similar manufacturing method from FIG. 1 to FIG. 3, that is to say, the manufacturing method of the device 200 is similar to the manufacturing of the device 100. In particular, a difference between the device 100 and the device 200 is that the device 200 is free from through via penetrating through the semiconductor layer. Here, the structures of the device 200, such as a semiconductor layer 210, a memory cell 220, an isolation layer 230, a circuit layer CL2 including a interconnect structure 240 (connecting lines 241, connecting vias 242, and dielectric layers 243) and a bonding structure 250 (a dielectric layer 251 and a bonding pads 252), and a protection layer 260, are similar to the structures of the device 100, such as semiconductor layer 110, the memory cell 120, the isolation layer 130, the circuit layer CL1 including the interconnect structure 140 (the connecting lines 141, the connecting vias 142, and the dielectric layers 143) and the bonding structure 150 (the dielectric layer 151 and the bonding pads 152), and the protection layer 160 respectively, and are not reiterated here. In the embodiment, the device 100 may be a master chip and the device 200 may be a slave chip in functionality.

After the device 100 and the device 200 are provided, the device 200 is bonded to the device 100 and the circuit layer CL1 is electrically connected to the circuit layer CL2 through the functional through via FTV. For example, a plurality of connectors 12 are formed between the device 100 and the device 200, wherein the connectors 12 include a functional connector 12F vertically overlapping the functional through via FTV and a dummy connector 12D vertically overlapping the dummy through via DTV. In the embodiment, the functional connector 12F is formed between the functional through via FTV and one of the bonding pads 252 of the circuit layer CL2, and the dummy connector 12D is formed between the insulating block 170 and another one of the bonding pads 252 of the circuit layer CL2.

In some embodiments, the functional through via FTV is physically and electrically connected to the functional connector 12F, and the dummy through via DTV is physically and electrically isolated to the dummy connector 12D through an insulating block 170. In the embodiment, the dummy through via DTV is spaced from the dummy connector 12D and the functional through via FTV is extending in the functional connector 12F.

It should be noted that the term “functional” is used to refer an element transmitting signal and power between two devices, and the term “dummy” is used to refer an element not transmitting signal and power between two devices in above description.

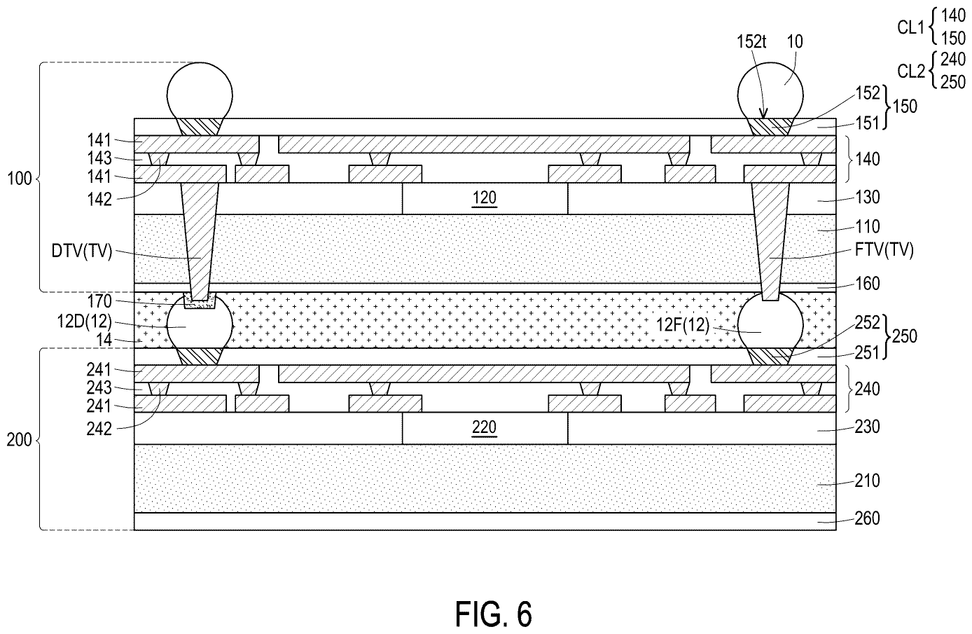

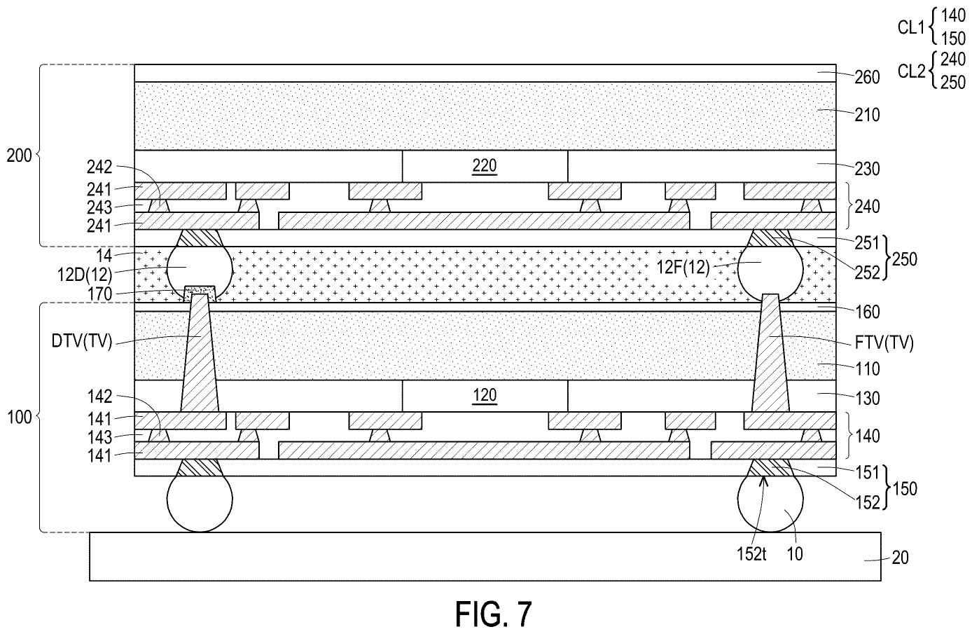

Referring to FIG. 6 and FIG. 7, an underfill 14 is filling a gap between the first device 100 and the second device 200 and surrounding the insulating block 170. And then, a substrate 20 is provided, and the device 100 and the device 200 may be bonded on the substrate 20 through the external terminals 10. For example, the external terminals 10, the device 100, and the device 200 are stacked on the substrate 20 sequentially. In some embodiments, the substrate 20 may be a printed circuit board (PCB), a semiconductor substrate or other substrates known in the art. In some embodiments, the underfill 14 may be resin or the like.

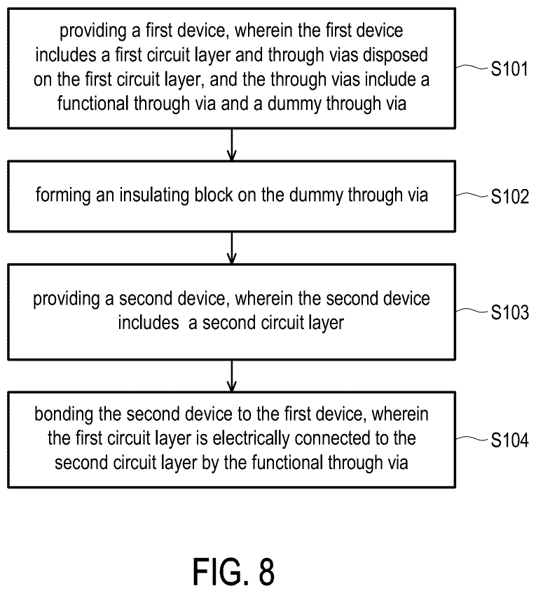

FIG. 8 is a flow diagram of some embodiments of a manufacturing method of an electronic stacked structure. The method includes a number of operations (blocks S101, S102, S103, and S104). The description and illustration are not deemed as a limitation to the sequence of the operations.

At block S101, provide a first device, wherein the first device includes a first circuit layer and through vias disposed on the first circuit layer, and the through vias include a functional through via and a dummy through via. FIG. 1 to FIG. 3 illustrate cross-sectional views of some embodiments corresponding to block S101.

At block S102, form an insulating block on the dummy through via. FIG. 4 illustrates cross-sectional view of some embodiments corresponding to block S102.

At block S103, providing a second device, wherein the second device includes a second circuit layer. At block S104, bond the second device to the first device, wherein the first circuit layer is electrically connected to the second circuit layer by the functional through via. FIG. 5 illustrates a cross-sectional view of some embodiments corresponding to block S103 and block S104.

In the present disclosure, the insulating block may flexibly be disposed at the position which needs to be disconnected of the through vias, such that vertical signal and power transmission through the through vias may be easily switched, thereby the circuit layouts may be maintained and the transmission states of the through vias may be controlled. In addition, the fuse circuit may be reduced or omitted, such that the size of the 3D electronic structure may be improved. Moreover, in the aforementioned design with the insulating block, the manufacturing cost may be decreased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic stacked structure, comprising:
a first device, comprising a first circuit layer and through vias disposed on the first circuit layer, wherein the through vias comprise a functional through via and a dummy through via;
an insulating block, directly covering and contacting the dummy through via; and
a second device, comprising a second circuit layer, wherein the first circuit layer is electrically connected to the second circuit layer through the functional through via.

2. The electronic stacked structure as claimed in claim 1, wherein portions of the dummy through via is embedded in the insulating block.

3. The electronic stacked structure as claimed in claim 1, wherein a thickness of the insulating block ranges from 0.3 micrometers to 0.5 micrometers.

4. The electronic stacked structure as claimed in claim 1, wherein a material of the insulating block is nitride.

5. The electronic stacked structure as claimed in claim 1, further comprising: connectors disposed between the first device and second device, wherein the connectors comprise a functional connector vertically overlapping the functional through via and a dummy connector vertically overlapping the dummy through via.

6. The electronic stacked structure as claimed in claim 5, wherein the functional through via is physically and electrically connected to the functional connector, and the dummy through via is physically and electrically isolated to the dummy connector through an insulating block.

7. The electronic stacked structure as claimed in claim 5, wherein the dummy through via is spaced from the dummy connector.

8. The electronic stacked structure as claimed in claim 5, wherein the functional through via is extending in the functional connector.

9. The electronic stacked structure as claimed in claim 1, further comprising an underfill filling a gap between the first device and the second device and surrounding the insulating block.

10. The electronic stacked structure as claimed in claim 1, wherein:
the first device further comprises a first semiconductor layer and a first memory cell disposed between the first semiconductor layer and the first circuit layer;
the through vias penetrating through the first semiconductor layer;
the second device further comprises a second semiconductor layer and a second memory cell disposed between the second semiconductor layer and the second circuit layer.

11. The electronic stacked structure as claimed in claim 10, wherein the first device further comprises a protection layer disposed on the first semiconductor layer and surrounding the through vias, and a material of the protection layer is different from a material of the insulating block.

12. The electronic stacked structure as claimed in claim 1, wherein the first device further comprises external terminals disposed on a surface of the first circuit layer away from the second device.

13. The electronic stacked structure as claimed in claim 12, further comprising: a substrate, wherein the external terminals, the first device, and the second device are stacked on the substrate sequentially.

14. A manufacturing method of an electronic stacked structure, comprising:
providing a first device, wherein the first device comprises a first circuit layer and through vias disposed on the first circuit layer, and the through vias comprise a functional through via and a dummy through via;
forming an insulating block on the dummy through via;
providing a second device, wherein the second device comprises a second circuit layer; and
bonding the second device to the first device, wherein the first circuit layer is electrically connected to the second circuit layer through the functional through via.

15. The manufacturing method of an electronic stacked structure as claimed in claim 14, wherein a step of the first device comprises:
providing a first semiconductor layer;
forming the through vias penetrating through the first semiconductor layer; and
removing portions of the first semiconductor layer from a side away from the first circuit layer to reveal the through vias.

16. The manufacturing method of an electronic stacked structure as claimed in claim 15, wherein the step of the first device further comprises:
forming a protection layer in a space generated by removing the portions of the first semiconductor layer, wherein a material of the protection layer is different from a material of the insulating block.

17. The manufacturing method of an electronic stacked structure as claimed in claim 16, wherein a step of forming the insulating block further comprises:
forming an insulating material on the protection layer; and
performing a photolithography process and an etching process to remove portions of the insulating material.

18. The manufacturing method of an electronic stacked structure as claimed in claim 14, further comprising:
forming a functional connector between the functional through via and the second circuit layer; and
forming a dummy connector between the insulating block and the second circuit layer.

19. The manufacturing method of an electronic stacked structure as claimed in claim 14, wherein the manufacturing steps of the first device further comprises:
forming external terminals on the first circuit layer, wherein the first circuit layer disposed between the external terminals and the through vias.

20. The manufacturing method of an electronic stacked structure as claimed in claim 19, further comprising: bonding the second device and the first device on a substrate through the external terminals.
